(19) United States
(12) Patent Application Publication
(10) Pub. No.: US 2025/0201647 A1
(43) Pub. Date: Jun. 19, 2025

(54) PACKAGE STRUCTURE

(71) Applicant: Richtek Technology Corporation, Zhubei City (TW)

(72) Inventors: Shih-Chieh LIN, Kaohsiung City (TW); Heng-Chi HUANG, Zhudong Township (TW); Yong-Zhong HU, Zhubei City (TW)

(21) Appl. No.: 18/585,414

(22) Filed: Feb. 23, 2024

(30) Foreign Application Priority Data
Dec. 15, 2023 (TW) 112149039

(51) Int. Cl. H01L 23/36; H01L 23/00; H01L 23/31; H01L 23/42; H01L 25/065

(52) U.S. Cl. CPC H01L 23/36; H01L 23/3121; H01L 23/42; H01L 24/16; H01L 24/32; H01L 24/73; H01L 25/0657; H01L 2224/16245; H01L 2224/32145; H01L 2224/73253

(57) ABSTRACT

The present disclosure provides a package structure. The package structure includes a lead frame, a first flip-chip disposed over the lead frame, a first dummy chip affixed on the first flip-chip by a non-conductive adhesive layer to serve as heat dissipation paths for the first flip-chip, and an encapsulant encapsulating the first flip-chip and the first dummy chip.

### TECHNICAL FIELD

The disclosure relates to packaging technology, and, in particular, to package structures that improve the heat dissipation effectiveness by using dummy chips.

### CROSS REFERENCE TO RELATED APPLICATIONS

This application claims priority of Taiwan Patent Application No. 112149039, filed on Dec. 15, 2023, the entirety of which is incorporated by reference herein.

### BACKGROUND

### Description of the Related Art

For packages with a lead frame architecture, integrated circuit (IC) chips primarily transmit IC signals to the package pins through wire bonding or a flip-chip with bumps. Generally, wire bonding provides better heat dissipation than bumps because IC chips are attached to exposed pads. The heat dissipation effectiveness in the bump form depends on the quantity of bumps. In a typical layout, the quantity of bumps that can be placed is limited. Therefore, heat dissipation is usually poorer than with wire bonding. However, the use of bumps results in low resistance compared to wire bonding, providing an advantage in terms of electrical properties.

In recent years, for the purpose of integrating IC chips with different functions within a limited space using packages with a lead frame architecture, the use of package-on-package (POP) has become common for packaging. However, the upper chip needs to be attached to the lower chip via a layer of non-conductive adhesive, which typically has poor thermal conductivity, leading to less-than-expected heat dissipation.

To address the above issues, some solutions have been proposed. For example, through grinding, the surface of the flip-chip is exposed (the same approach is applied to the upper chip in the POP configuration) to facilitate the direct installation of a heat sink on the chip's surface, thereby accelerating heat dissipation. However, exposing the silicon surface directly often leads to issues with electrostatic discharge (ESD), causing charge accumulation and discharge, thereby affecting IC signals.

In addition to the ESD issue, if the surface of a silicon chip is exposed by grinding, the package thickness will be constrained, making it difficult to adjust the package thickness to match all package moldings. Moreover, IC chips are typically controlled to a thickness of within 12 mils for ease of cutting, while taking factors such as tool wear and production rate into consideration. Therefore, it is impossible to increase the thickness of IC chips to meet the desired package thickness.

### SUMMARY

An embodiment of the present disclosure provides a package structure. The package structure includes a lead frame, a first flip-chip disposed over the lead frame, a first dummy chip affixed on the first flip-chip by a non-conductive adhesive layer to serve as heat dissipation paths for the first flip-chip, and an encapsulant encapsulating the first flip-chip and the first dummy chip.

An embodiment of the present disclosure provides a package structure. The package structure includes a circuit board, a plurality of package structures of claim 10 disposed on the circuit board, a plurality of first external connectors electrically connecting the heat sinks to the circuit board, and at least one second external connector electrically connecting the heat sinks of adjacent package structures. Each of the heat sinks has a different potential.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-3 are cross-sectional views of various stages of manufacturing a package structure, in accordance with some embodiments.

FIG. 4 is a cross-sectional view of a package structure having a second flip-chip, in accordance with some other embodiments.

FIGS. 5-8 are cross-sectional views of various stages of manufacturing a package structure in which a first flip-chip has trenches, in accordance with some further embodiments.

FIG. 9 is a cross-sectional view of a package structure in which the first flip-chip further includes a thermal conductivity material filling the trenches, in accordance with some further embodiments.

FIGS. 10-13 are cross-sectional views of various stages of manufacturing a package structure having a second dummy chip, a heat sink, and a circuit board, in accordance with yet further embodiments.

FIG. 14 is a cross-sectional view of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with the embodiments of the present disclosure, regarding terms such as “connected,” “interconnected,” and the like. referring to bonding and connection, unless otherwise defined, these terms mean that two structures are in direct contact, or two structures are not in direct contact and other structures are provided to be disposed of between the two structures. Moreover, terms referring to bonding and connection may also include the situation where both structures are movable or both structures are fixed. In addition, the terms “electrical connected” or “coupling connected” include any direct and indirect means of electrical connection.

Further, when a number or a range of numbers is described with “about,” “approximate,” or “substantially,” and the like, the term is intended to encompass numbers that are within a reasonable range, including the number described, such as within +/−10% of the number described as understood by one of the ordinary skill in the art. For example, the term “about 5 nm” can encompass the size range from 4.5 nm to 5.5 nm. The stated value of the present disclosure is an approximate value. When there is no specific description, the stated value includes the meaning of “about,” “approximate,” or “substantially.”

It should be noted that the following embodiments can replace, recombine, and combine features in several different embodiments to complete other embodiments without departing from the spirit of the present disclosure. The features between the various embodiments can be combined and used arbitrarily, as long as they do not violate or conflict with the spirit of the present disclosure.

Unless otherwise defined, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or context of the present disclosure, and should not be interpreted in an idealized or overly formal manner unless so defined.

To address the drawbacks of the prior art, the present disclosure provides a package structure, in which a non-functional dummy chip is affixed on the IC chip to address the problem of heat dissipation (for example, undesirable heat dissipation), but the present disclosure is not limited thereto. The present disclosure can also address other issues, such as electrical issues (for example, electrostatic discharge (ESD) issues) or production issues (for example, the inability to match all package molding requirements).

In some embodiments of the present disclosure, the term “dummy chip” refers to a chip without IC signals, unless otherwise defined.

The package structure of the present disclosure may be used in quad flat no lead package (QFN), quad flat package (QFP), dual in-line package (DIP), small outline package (SOP), small outline transistor package (SOT), and system on integrated chip package (SOIC), but the present disclosure is not limited thereto. It may applied to other package structures with lead frames based on practice needs. The content of the present will be described below using QFN, but the present disclosure is not limited thereto.

Some variations of the embodiments are described below. Throughout the various drawings and illustrative embodiments, the same or like reference numerals are used to designate the same or like elements.

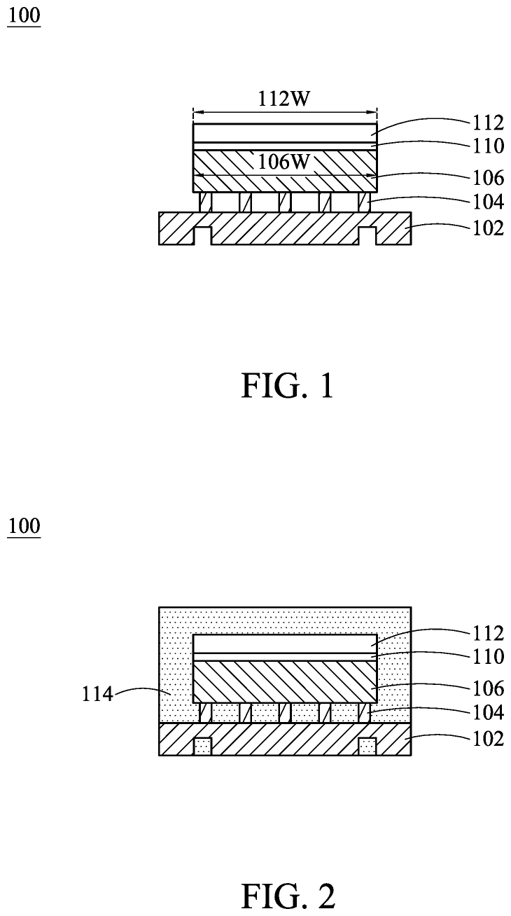

FIGS. 1-3 are cross-sectional views of various stages of manufacturing a package structure 100, in accordance with some embodiments. Referring to FIG. 1, in an embodiment, a first flip-chip 106 is affixed on and electrically connected to a lead frame 102 through a plurality of bumps 104. In some embodiments, the bumps 104 are disposed on the front side (the side facing downward in FIG. 1) having the circuit components of the first flip-chip 106, and then the first flip-chip 106 is flipped so that the bumps 104 are directly connected to the connection points (e.g., pins, not shown) on the lead frame 102 to achieve electrical connection.

The lead frame 102 may include a die pad (not shown) and a plurality of connection points (not shown). In this embodiment, a plurality of recessed portions at the bottom of the lead frame 102 are represented as an area not occupied by functional components (e.g., the chip pad and the connection points). The areas are filled with an encapsulant 114 (FIG. 2) in the subsequent processes. In other embodiments, the lead frame 102 may broadly refer to a substrate with metal routing.

In some embodiments, the bumps 104 serve as heat dissipation paths for the first flip-chip 106 and transfer the heat generated by the first flip-chip 106 downward to the lead frame 102 for heat dissipation. However, the heat dissipation effectiveness depends on the quantity of the bumps 104, and typically, there is a limited number of bumps 104 that can be arranged in a standard IC chip layout. In other words, if the quantity of the bumps 104 is reduced, the heat dissipation effectiveness of the first flip-chip 106 decreases

In some embodiments, the bumps 104 may include a variety of shapes, such as square, circular, elliptical, polygonal, and the like. The shape can be determined based on manufacturing or signal connection requirements In some embodiments, the material of the bumps 104 may include a single metal (e.g., tin or copper), an alloy (e.g., tin-silver alloy or tin-lead alloy), a composite material structure (e.g., tin-silver-copper alloy), or other suitable materials. In some embodiments, the bumps 104 may be formed on the connection points of the first flip-chip 106 by an electroplating process or a ball mounting process.

In some embodiments, the backside of the first flip-chip 106 (the side facing upward in FIG. 1) has a flat surface to facilitate the placement of the first dummy chip 112 and the second dummy chip 113 (as shown in FIG. 10) thereon during the subsequent process.

Referring to FIG. 1, in an embodiment, the first dummy chip 112 is affixed on the first flip-chip 106 through a non-conductive adhesive layer 110 to serve as heat dissipation paths for the first flip-chip 106.

In some embodiments, the non-conductive adhesive layer 110 is used to prevent ESD issues caused by the surface of the first dummy chip 112 exposed while protecting the IC chip from external factors (e.g., physical damage, chemical erosion, or the like) that could affect the IC signals. In addition, the non-conductive adhesive layer 110 can be used to electrically isolate the first flip-chip 106 from the first dummy chip 112 to prevent the first dummy chip 112 from affecting the IC signals of the first flip-chip 106.

In some embodiments, the non-conductive adhesive layer 110 may include non-conductive paste (NCP), non-conductive film (non-conductive film, NCF), or other suitable non-conductive adhesive materials, but the present disclosure is not limited thereto. In other embodiments, conductive adhesive can be used in conjunction with non-conductive dummy chips, as long as it avoids ESD issues on the surface of the first dummy chip 112. In some embodiments, the adhesive layer can contain commonly used components in the field of non-conductive adhesives or non-conductive films, such as thermoplastic resin, thermosetting resin, curing agent, inorganic filler, and catalyst. In some embodiments, the non-conductive adhesive layer 110 may formed on the first flip-chip 106 by printing, spraying, or bonding.

In some embodiments, the thickness of the non-conductive adhesive layer 110 is 10 um to 50 um. Generally, since the thermal conductivity coefficient of the non-conductive adhesive layer 110 is low (e.g., 0.3 W/(m·K) or less than 0.6 W/(m·K)), a thicker layer results in greater thermal resistance, leading to a significant reduction in the heat dissipation effectiveness. For example, if the thickness of the non-conductive adhesive layer 110 is increased from 10 um to 20 um (increased to two times), the thermal resistance will become twice the original value.

In some embodiments, the first dummy chip 112 may serve as additional heat dissipation paths for the first flip-chip 106 (i.e., except for the above-described bumps 104). As mentioned above, the bumps 104 serve as heat dissipation paths for the first flip-chip 106, but the heat dissipation effectiveness depends on the quantity of bumps 104. In addition, generally, the backside of the first dummy chip 112 (the side facing upward in FIG. 1) only relies on air convection for heat dissipation, so the heat dissipation effectiveness is undesirably low. To address the above issue, in the present disclosure, the first slip-chip 106 is bonded to the first dummy chip 112 to improve the heat dissipation effectiveness since the first dummy chip 112 of the present disclosure has a high thermal conductivity coefficient e.g., 107.5 W/(m·K) to 147 W/(m·K) at 125° C.).

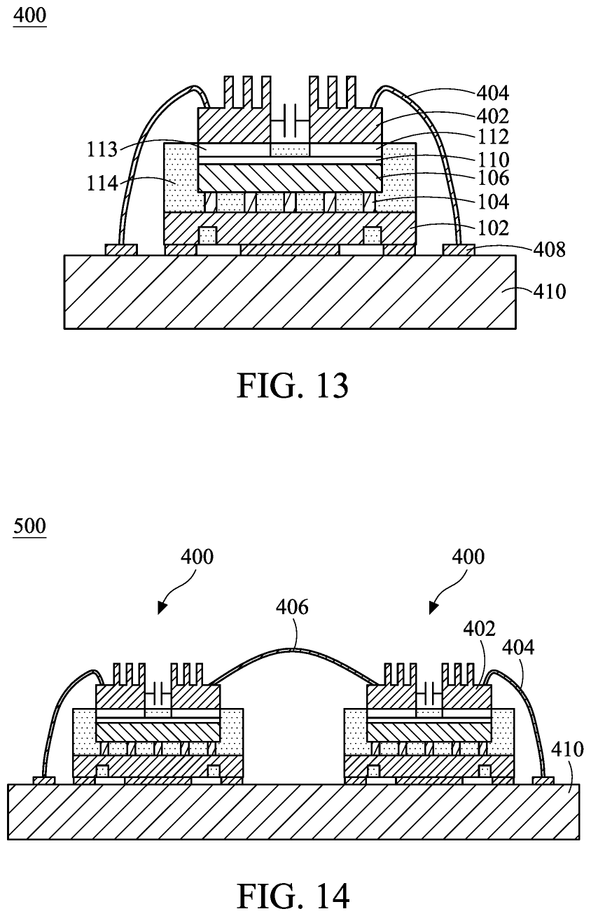

Generally, for ease of production, the molds used for package molding typically have several common fixed sizes. However, if the surface of the first flip-chip 106 is exposed by grinding to ensure direct contact with a subsequently installed heat sink (e.g., the heat sink 402 in FIG. 13), not only does this make it challenging to meet the expected package thickness, but it also hinders the adjustment of package thickness to comply with all mold sizes, thereby reducing throughput. In some embodiments, the present disclosure allows for the adjustment of the thickness of the first dummy chip 112 to meet the desired package thickness without increasing the thickness of the first flip-chip 106. This resolves the issue of not being able to meet the mold sizes for package.

In some embodiments, the first dummy chip 112 may include a silicon chip without functional circuits, a silicon chip or a silicon carbide chip designated for disposal, or any materials with a high thermal conductivity coefficient and easy to cut. In an embodiment, the width 112W of the first dummy chip 112 is greater than the width 106W of the first flip-chip 106 in the cross-sectional view. This increases the heat dissipation area of the first flip-chip 106 and also shield it from external electromagnetic waves. In an embodiment, the width 112W of the first dummy chip 112 is smaller than the width 106W of the first flip-chip 106 in the cross-sectional view. The first dummy chip 112 with a smaller width has a better bonding force with the encapsulant 114 (FIG. 2), thus preventing the encapsulant 114 from peeling off the surface of the first dummy chip 112 in subsequent processes.

Next, referring to FIG. 2, in an embodiment, the encapsulant 114 is used to encapsulate the first flip-chip 106 and the first dummy chip 112. As shown in the figure, the encapsulant 114 covers multiple side surfaces of the first flip-chip 106, the top surface and multiple side surfaces of the first dummy chip 112, and fills the gaps between the first flip-chip 106 and the lead frame 102 (e.g., the gaps between the bumps 104). In some embodiments, the encapsulant 114 is used to protect the package structure 100 from external factors (e.g., moisture or dust) and maintain the stability and yield of the package structure 100.

In some embodiments, the encapsulant 114, also known as a molding compound, may include an epoxy, a resin, a moldable polymer, combinations thereof, or other suitable materials. The encapsulant 114, such as epoxy or resin, may be applied in a substantially liquid state and then cured through a chemical reaction. In some other embodiments, the encapsulant 114 may be an ultraviolet (UV) or thermally cured polymer, which can be in the form of a gel or a malleable solid arranged around the first flip-chip 106 and the first dummy chip 112, and then may be cured using a UV or thermal curing process. In some embodiments, the encapsulant 114 may be formed by compression molding, injection molding, transfer molding, or other suitable packaging methods.

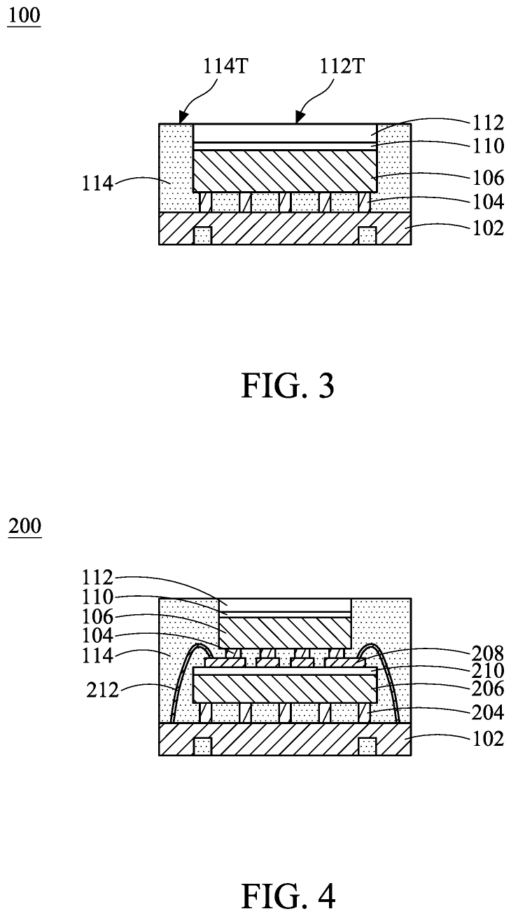

Next, referring to FIG. 3, in some embodiments, the excess encapsulation 114 is removed by a grinding process to expose the top surface 112T of the first dummy chip 112. In an embodiment, the first dummy chip 112 has a flat top surface 112T co-planar with the top surface 114T of the encapsulation 114. In some embodiments, any form of heat sink can be assembled on the first dummy chip 112 having the flat top surface 112T. In some embodiments, the grinding process may include a chemical mechanical polishing (CMP) process, mechanical grinding, or other suitable processes, but the present disclosure is not limited thereto.

As shown in FIG. 3, a package structure 100 of the present disclosure includes a lead frame 102, a first flip-chip 106 disposed over the lead frame 102, a first dummy chip 112 affixed on the first flip-chip 106 by a non-conductive adhesive layer 110, and an encapsulant 114 encapsulating the first flip-chip 106 and the first dummy chip 112. The first dummy chip 112 serves as heat dissipation paths for the first flip-chip 106.

FIG. 4 is a cross-sectional view of a package structure 200 having a second flip-chip 206, in accordance with some other embodiments. It should be noted that the features between the various embodiments can be combined and used arbitrarily as long as they do not violate or conflict the spirit of the present disclosure.

The package structure 200 in FIG. 4 is similar to the package structure 100 in FIG. 3, except that the package structure 200 further includes a second flip-chip 206 disposed between the first flip-chip 106 and the lead frame 102, and both the first flip-chip 106 and the second flip-chip 206 are electrically connected to the lead frame 102. Specifically, the second flip-chip 206 is affixed on and electrically connected to the lead frame 102 through a plurality of bumps 204, and then the first flip-chip 106 is affixed on the second flip-chip 106 through a plurality of bumps 104. The first flip-chip 106 is electrically connected to the lead frame 102 through a plurality of connection points 208 and connectors 212. In some embodiments, connection points 208 may include metal pads, metal pillars, under bump metallurgies (UBMs), or other suitable bonding materials. In some embodiments, the connectors 212 electrically connect the heat sink 402 and the circuit board 410 by wire bonding.

It should be noted that although there are only two flip-chips shown in FIG. 4, any number of flip-chips can be arranged on the lead frame 102 according to design requirements. For example, the package structure 200 may include three or even more than four flip-chips stacked vertically, but the disclosure is not limited thereto.

It should be noted that the heat dissipation effectiveness for the first flip-chip 106 is worse than that of the second flip-chip 206 since the first flip-chip 106 is further away from the lead frame 102 and is separated from the second flip-chip 206 by the non-conductive adhesive layer 210 with a low thermal conductivity. However, with the first dummy chip 112 provided by the present disclosure, an additional heat dissipation path for the first flip-chip 106 is created, thus further improving the heat dissipation effectiveness for the first flip-chip 106.

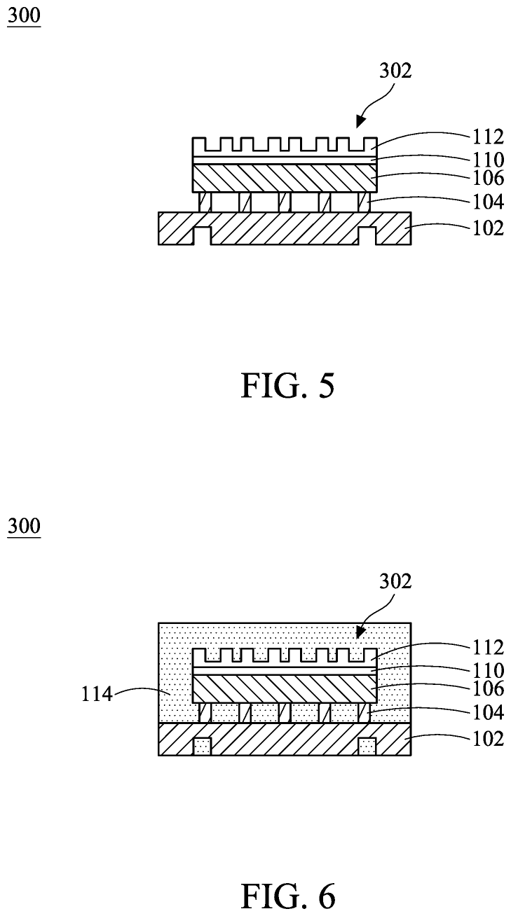

FIGS. 5-8 are cross-sectional views of various stages of manufacturing a package structure 300 in which a first dummy chip 112 has trenches 302, in accordance with further embodiments.

In some embodiments, FIG. 5 follows the steps depicted in FIG. 1. The package structure 300 in FIG. 5 is similar to the package structure 100 in FIG. 1, except that the first dummy chip 112 includes a plurality of trenches 302. In some embodiments, the trenches 302 can increase the surface area of the first flip-chip 106, thereby increasing its heat dissipation area. Moreover, the distance between the bottom of the trenches 302 and the first flip-chip 106 is shorter (the thickness of the first dummy chip 112 in this area is thinner), resulting in a smaller thermal resistance. As shown in the figure, in some embodiments, the first dummy chip 112 may have a fin-like shape, but the present disclosure is not limited thereto. The number, shape, and arrangement of the trenches 302 can be configured according to design requirements.

In some embodiments, a patterning process may be used to form a plurality of trenches 302 on the surface of the first dummy chip 112. In some embodiments, the patterning process may include a photolithography process and an etching process using a photomask to define a photoresist pattern on the first dummy chip 112 to be patterned, and then the photoresist pattern is used as a mask to etch the first dummy chip 112 to form the trenches 302. In some embodiments, the photolithography process may include, but is not limited to, photoresist coating (e.g., spin coating), soft baking, hard baking, mask alignment, exposure, post-exposure baking, photoresist development, cleaning, and drying. The etching process may include, but is not limited to, dry etching process, wet etching process, reactive ion etching (RIE), ashing, and/or other etching methods.

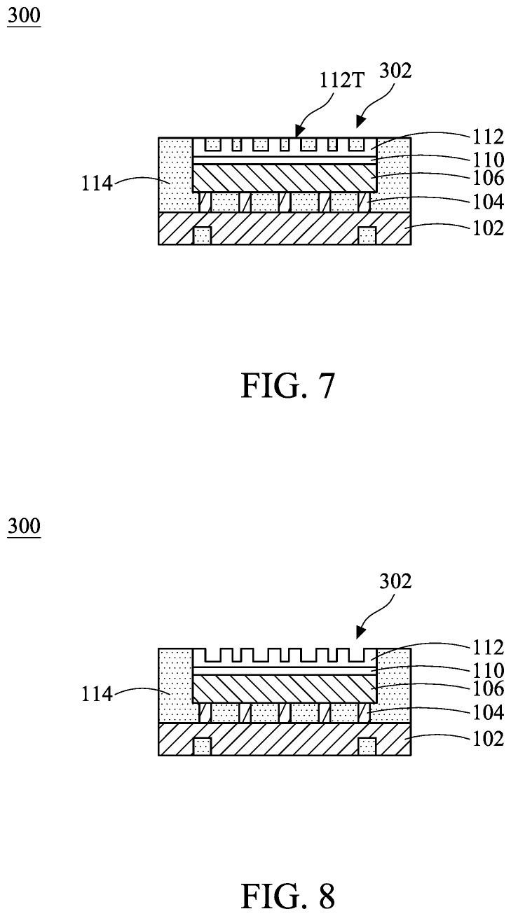

Next, referring to FIGS. 6-7, in some embodiments, the first flip-chip 106 and the first dummy chip 112 are encapsulated with the encapsulant 114, and the excess encapsulation 114 is then removed by a grinding process to expose the top surface 112T of the first dummy chip 112. The manufacturing steps in FIGS. 6-7 are similar to the manufacturing steps in FIGS. 2-3, and their details will not be repeated herein for brevity.

Next, referring to FIG. 8, in some embodiments, after removing the excess encapsulant 114 to expose the top surface 112T of the first dummy chip 112, the encapsulant 114 in the trenches 302 is also removed. In some embodiments, the encapsulant 114 in the trenches 302 may be removed by a wet chemical etching process. Specifically, a mask is disposed around the first dummy chip 112 to protect the encapsulant 114 outside the trenches 302 from being etched away during the removal of the encapsulant 114 from the trench 302, and the mask may be removed thereafter, but the present disclosure is not limited thereto. As shown in the figure, the encapsulant 114 in the trenches 302 is removed by the wet chemical etching process, but the encapsulant 114 around the first dummy chip 112 is not substantially removed.

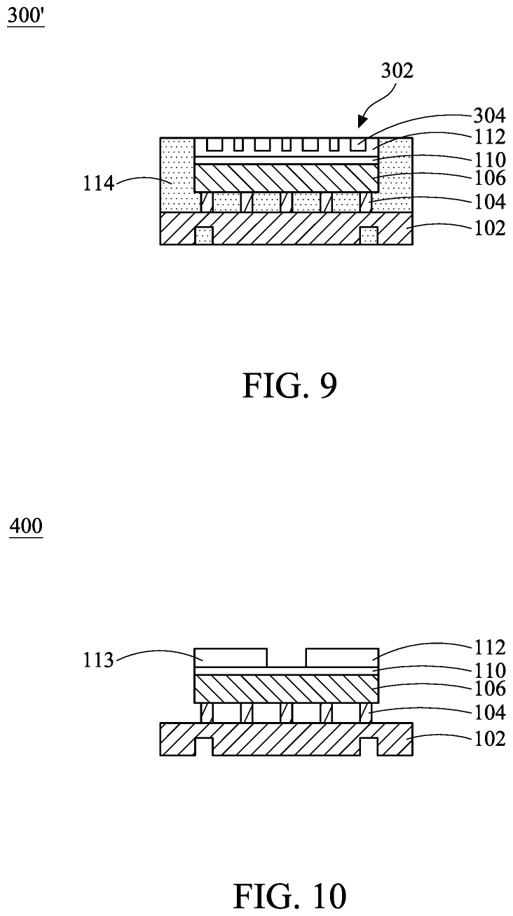

FIG. 9 is a cross-sectional view of a package structure 300′ in which the first dummy chip 112 further includes a thermal conductivity material 304 filling the trenches 302, in accordance with some further embodiments. In some embodiments, the thermal conductivity material 304 has a desired thermal conductivity coefficient (e.g., greater than 149 W/(m·K)) or a higher thermal radiation capability than the first dummy chip 112, which can further improve the heat dissipation effectiveness for the first flip-chip 106. In some embodiments, the thermal conductivity material 304 may include thermal grease, which is composed of silicone or hydrocarbons and added with various fillers, but the present disclosure is not limited thereto. In some embodiments, the molten thermal conductivity material 304 is filled into the trenches 302 and cured. In some embodiments, the thermal conductivity material 304 completely fills the trenches 302. In other words, the top surface of the first flip-chip 106 is co-planar with the top surface of the thermal conductivity material 304, and thus any form of heat sink can be assembled thereon.

FIGS. 10-13 are cross-sectional views of various stages of manufacturing a package structure 400 having a second dummy chip 113, heat sinks 402, and a circuit board 410, in accordance with yet further embodiments.

The package structure 400 in FIG. 10 is similar to the package structure 100 in FIG. 1, except that the package structure 400 further includes a second dummy chip 113, which is juxtaposed to and spaced apart from the first dummy chip 112 on the first flip-chip 106. In some embodiments, the second dummy chip 113 and the first dummy chip 112 are substantially the same, and both can serve as heat dissipation paths for the first flip-chip 106. It should be noted that although there are only two dummy chips shown in FIG. 10 (e.g., the first dummy chip 112 and the second dummy chip 113), any number of dummy chips can be arranged on the first flip-chip 106 according to design requirements. For example, the package structure 400 may include three or even more than four dummy chips spaced apart from each other, but the disclosure is not limited thereto.

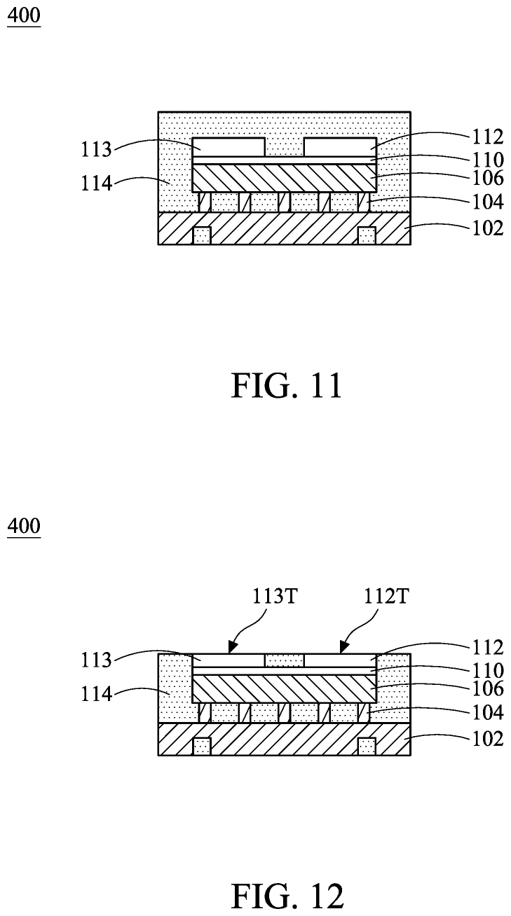

Next, referring to FIGS. 11-12, in some embodiments, the first flip-chip 106, the first dummy chip 112, and the second dummy chip 113 are encapsulated with the encapsulant 114, and the excess encapsulation 114 is then removed by a grinding process to expose the top surface 112T of the first dummy chip 112 and the top surface 113T of the second dummy chip 113. The manufacturing steps in FIGS. 11-12 are similar to the manufacturing steps in FIGS. 2-3, and their details will not be repeated herein for brevity.

Next, referring to FIG. 13, in an embodiment, the package structure 400 further includes a plurality of heat sinks 402 affixed on the first dummy chip 112 and the second dummy chip 113. As shown in the figure, two heat sinks 402 are affixed on the first dummy chip 112 and the second dummy chip 113, respectively. It should be noted that although there are only two heat sinks shown in FIG. 13, any number of heat sinks can be arranged thereon according to the numbers of the dummy chips. For example, in accordance with an embodiment including three dummy chips, the package structure 400 may include three heat sinks affixed on three dummy chips, respectively, but the disclosure is not limited thereto.

In some embodiments, the heat sinks 402 are in the form of a heat slug, a heat spreader, a heat sink fin, a heat pipe, or other suitable forms of heat sink. In some embodiments, the heat sinks 402 can be adhered to the surface of the first dummy chip 112 and/or the second dummy chip 113 through a thermal conductive adhesive.

In one embodiment, the package structure 400 further includes a circuit board 410 disposed under the lead frame 102 and a plurality of first external connectors 404 electrically connecting the heat sinks 402 to the circuit board 410. Specifically, the heat sinks 402 are electrically connected to the circuit board 410 through the first external connectors 404 and a plurality of connection points 408. In some embodiments, the connection points 408 may include metal pads, metal pillars, under bump metallurgies (UBMs), or other suitable bonding materials. In some embodiments, the circuit board 410 may include a printed circuit board (PCB), a flexible printed circuit (FPC), or other suitable circuit boards.

In one embodiment, each of the heat sinks 402 has different potentials, serving not only to further improve heat dissipation of the first flip-chip 106, but also as an external capacitor, thus allowing for a reduction in the area of the first flip-chip 106. In some embodiments, the heat sinks 402 may be electrically connected to the circuit board 410 through the first external connectors 404 by wire bonding.

FIG. 14 is a cross-sectional view of a package structure 500, in accordance with some embodiments. In one embodiment, the present disclosure further provides a package structure 500. The package structure 500 includes a circuit board, a plurality of package structures of claim 10 disposed on the circuit board, a plurality of first external connectors electrically connecting the heat sinks to the circuit board, and at least one second external connector electrically connecting the heat sinks of adjacent package structures. Each of the heat sinks has a different potential.

It should be noted that although there are only two package structures 400, two first external connectors 404, and a second external connector 406 shown in FIG. 14, any number of package structures 400, first external connectors 404, and second external connectors 406 can be arranged on the circuit board 410 according to design requirements. For example, in accordance with an embodiment including three package structures 400, the package structure 500 may include three first external connectors 404 and three second external connectors 406. The first external connectors 404 electrically connect three package structures 400 to the circuit board 410, respectively, and the second external connectors 406 electrically connect the heat sinks 402 of three package structures 400 to each other, but the disclosure is not limited thereto.

In some embodiments, the second external connectors 406 are similar to the first external connectors 404, except that the first external connectors 404 are used to electrically connect the heat sinks 402 to the circuit board 410, and the second external connectors 406 are used to electrically connect (e.g., in series or in parallel) the heat sinks 402 of the adjacent package structures 400.

In summary, various embodiments of the present disclosure provide a package structure. The package structure includes a dummy chip without signals affixed on the IC chip. Therefore, the IC chip can not only dissipate heat downward to the circuit board through the bumps but also use the dummy chip as additional heat dissipation paths. Moreover, the package structure allows for the processing and filling of high thermal conductivity materials on the dummy chip to improve the heat dissipation effectiveness. In addition, the non-conductive adhesive layer between the IC chip and the dummy chip can prevent ESD issues caused by the surface of the first dummy chip exposed while protecting the IC chip from external factors (e.g., physical damage, chemical erosion, or the like) affecting the IC signal. Further, the thickness of the dummy chip can be adjusted to meet the desired package thickness and resolve issues related to mold size compliance. Furthermore, the dummy chip provides a flat surface for accommodating various forms of heat sinks in the packaging, and it can also be combined with multiple heat sinks to form an external capacitor, thereby integrating passive components to reduce space.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure, comprising:
a lead frame;
a first flip-chip disposed over the lead frame;
a first dummy chip affixed on the first flip-chip by a non-conductive adhesive layer to serve as heat dissipation paths for the first flip-chip; and
an encapsulant encapsulating the first flip-chip and the first dummy chip.

2. The package structure of claim 1, wherein the first flip-chip is affixed on and electrically connected to the lead frame through a plurality of bumps.

3. The package structure of claim 2, wherein the bumps are made of a single metal, an alloy, or a composite material.

4. The package structure of claim 1, wherein the first dummy chip has a flat top surface co-planar with a top surface of the encapsulant.

5. The package structure of claim 1, wherein a width of the first dummy chip is greater than a width of the first flip-chip in a cross-sectional view.

6. The package structure of claim 1, wherein a width of the first dummy chip is smaller than a width of the first flip-chip in a cross-sectional view.

7. The package structure of claim 1, wherein the non-conductive adhesive layer comprises non-conductive paste (NCP) or non-conductive film (NCF).

8. The package structure of claim 1, wherein a thickness of the non-conductive adhesive layer is 10 um to 50 um.

9. The package structure of claim 1, further comprising a second flip-chip disposed between the first flip-chip and the lead frame, wherein both the first flip-chip and the second flip-chip are electrically connected to the lead frame.

10. The package structure of claim 1, wherein the first dummy chip comprises a plurality of trenches.

11. The package structure of claim 10, wherein the first dummy chip has a fin-like shape in a cross-sectional view.

12. The package structure of claim 10, wherein the first dummy chip further comprises a thermal conductivity material filling the trenches.

13. The package structure of claim 1, wherein the thermal conductivity material is a thermal grease.

14. The package structure of claim 1, wherein the encapsulant is made of epoxy, resin, moldable polymer, or a combination thereof.

15. The package structure of claim 1, further comprising a second dummy chip being juxtaposed to and spaced apart from the first dummy chip on the first flip-chip.

16. The package structure of claim 15, further comprising a plurality of heat sinks affixed on the first flip-chip and the second flip-chip.

17. The package structure of claim 16, wherein the heat sinks are in a form of a heat slug, a heat spreader, a heat sink fin, or a heat pipe.

18. The package structure of claim 16, further comprising a circuit board disposed under the lead frame and a plurality of first external connectors electrically connecting the heat sinks to the circuit board, wherein each of the heat sinks has a different potential.

19. The package structure of claim 18, wherein the circuit board is a printed circuit board (PCB) or a flexible printed circuit (FCB).

20. A package structure, comprising:
a circuit board;
a plurality of package structures of claim 10 disposed on the circuit board, wherein each of the heat sinks has a different potential;
a plurality of first external connectors electrically connecting the heat sinks to the circuit board; and
at least one second external connector electrically connecting the heat sinks of adjacent ones of the package structures.
